(19) United States
(12) Patent Application Publication
(10) Pub. No.: US 2025/0006643 A1
(43) Pub. Date: Jan. 2, 2025

(54) METHODS OF FORMING WAFER LEVEL MULTI-DIE SYSTEM FABRIC INTERCONNECT STRUCTURES

(71) Applicant: Intel Corporation, Santa Clara, CA (US)

(72) Inventors: Debendra Mallik, Chandler, AZ (US); Ram Viswanath, Phoenix, AZ (US); Xavier Brun, Hillsboro, OR (US)

(73) Assignee: Intel Corporation, Santa Clara, CA (US)

(21) Appl. No.: 18/217,049

(22) Filed: Jun. 30, 2023

(51) Int. Cl. H01L 23/538; H01L 21/48; H01L 23/00; H01L 23/373; H01L 23/498; H01L 25/065

(52) U.S. Cl. CPC H01L 23/5381; H01L 21/486; H01L 23/3738; H01L 23/49816; H01L 23/49894; H01L 23/5386; H01L 24/08; H01L 24/16; H01L 25/0655; H01L 2224/08245; H01L 2224/16227; H01L 2924/15311

(57) ABSTRACT

Microelectronic integrated circuit package structures include a package substrate with a first die over the package substrate, and a second die adjacent to the first die, such that first sides of the first die and the second die are on a thermal solution. A bridge structure is directly on a portion of each of second sides of the first and second dies, such that the second sides include integrated circuit contact structures. Bridge via structures couple the integrated circuit contact structures to the bridge structure.

### BACKGROUND

In electronics manufacturing, integrated circuit (IC) packaging is a stage of manufacture where an IC that has been fabricated on a die or chip comprising a semiconducting material is coupled to a supporting case or “package” that can protect the IC from physical damage and support electrical interconnect suitable for further connecting to a host component, such as a printed circuit board (PCB). In the IC industry, the process of fabricating a package is often referred to as packaging, or assembly.

As demand for high performance computing (HPC) continues to rise, integration of heterogeneous devices within an IC package has become an important performance driver. Some high density die-to-die interconnect schemes utilize a silicon bridge die. A bridge die can provide high wiring density by leveraging standard silicon wafer manufacturing processing, as well as providing robust mechanical and environmental protections of fine pitch wiring. Common bridge schemes include embedded multi-die interconnect bridge structures, where the silicon bridge die is embedded in the package substrate, and utilizing an interposer layer that integrates a bridge die. However, large die area consumption and wire length considerations can limit the maximum signal bandwidth achievable with such die interconnect schemes.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A and FIG. 1C are cross-sectional views of IC package structures comprising die-to-die bridge structures, in accordance with some embodiments.

FIG. 1B is a top view of an IC package structure comprising die-to-die bridge structures, in accordance with some embodiments.

FIGS. 2A-2M illustrate cross-sectional views of structures formed during the fabrication of package structures having die-to-die bridge structures, in accordance with some embodiments.

FIG. 3 illustrates a flow chart of a process for the fabrication of IC package structures having die-to-die bridge structures, in accordance with some embodiments.

FIG. 4 is a functional block diagram of an electronic computing device, in accordance with some embodiments of the present disclosure.

### DETAILED DESCRIPTION

Embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause and effect relationship).

The terms “over,” “under,” “between,” and “on” as used herein refer to a relative position of one component or material with respect to other components or materials where such physical relationships are noteworthy. For example in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the explicit context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “dielectric” generally refers to any number of non-electrically conductive materials that make up the structure of a package substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

Views labeled “cross-sectional”, “profile” and “plan” correspond to orthogonal planes within a Cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments discussed herein address problems associated with packaging architectures and methods employing die-to-die interconnect structures. Such methods include the use of bridge structures to produce high density die-to-die interconnect structures for use within a system on a chip (SOC) architecture. Challenges associated with producing high bandwidth, low power interconnect structures between die such as between silicon chiplets for example include large die area consumption and long wire lengths requirements. Current die-to-die interconnect schemes limit signal bandwidth and bump pitch, which can negatively affect device performance of SOC package structures. The incorporation of high bandwidth, low power interconnect structures employing direct die-to-die interconnect structures directly on the surface of functional die enables the fabrication of cost effective, high performance SoC architectures, as described in the embodiments herein.

Embodiments describe interconnect bridge structures formed directly on chiplets/dies using silicon metal layer processes, such as deposition and lithographic processes. The bridge structures described herein are formed directly over the SoC constituent chiplets and enables very high density interconnect pitch of greater than about 1K wires/mm per metal layer. Further advantages of the embodiments presented herein include the enablement of 9 mm pad pitch or less by minimizing die-to-die circuit area as well as reducing conductive trace lengths to below about 200 microns.

Die-to-die interconnect structures and package structures fabricated according to the assembly processes of the embodiments herein may include first sides of a first die and a second die coupled to a package substrate. Second sides of the first and second die are on a surface of a thermal solution with a die spacer between the first and second dies. A bridge structure comprising a plurality of conductive traces is directly on a portion of an active side of the first die and is directly on an active side of the second die.

The dies may comprise a processor die or a memory component, for example, or any other suitable microelectronic components. In an embodiment, the dies may comprise chiplets of a SOC. A dielectric spacer occupies a space between the first die and the second die.

Terminal ends of individual conductive traces of the bridge structure are coupled to metal features in the active areas of the first and second dies, where an inorganic dielectric layer is between the active areas and the bridge structure. System level metal regions, comprising pluralities of conductive traces, are adjacent to the bridge structure on the inorganic dielectric layer. By forming the bridge structure directly on the active areas of the first and second dies, high density interconnect pitch and reduced pad pitch is enabled. Higher signal bandwidth is achieved by utilizing the embodiments herein within SOC architectures. The embodiments incorporate integrated multi-die interconnect bridge metal and dielectric layers to provide high density lateral connection between neighboring dies.

The architecture described herein may be assembled and/or fabricated with one or more of the features or attributes provided in accordance with various embodiments. A number of different assembly and/or fabrication methods may be practiced to fabricate bridge interconnect structures directly on adjacent die within a SOC package structure, according to one or more of the features or attributes described herein.

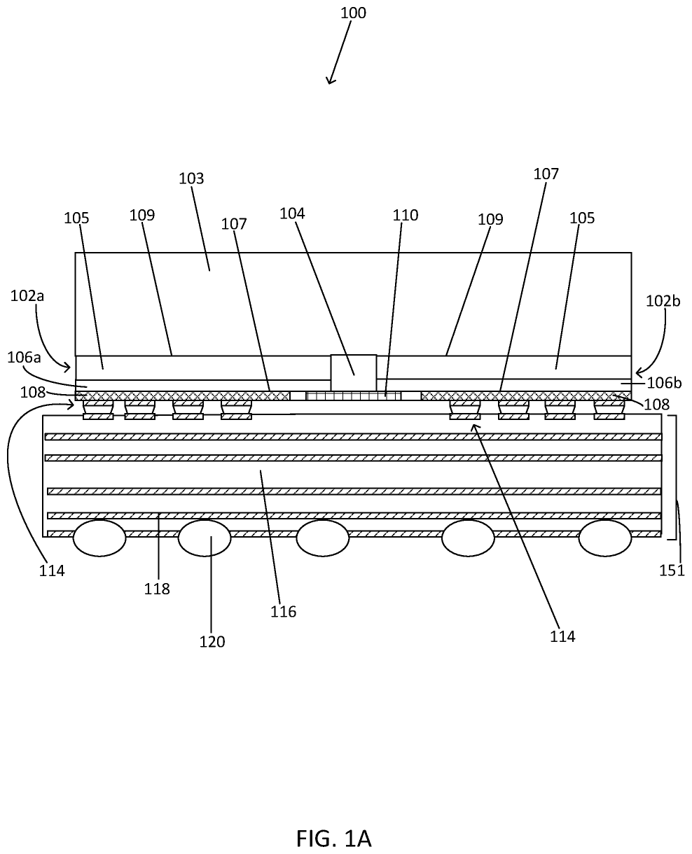

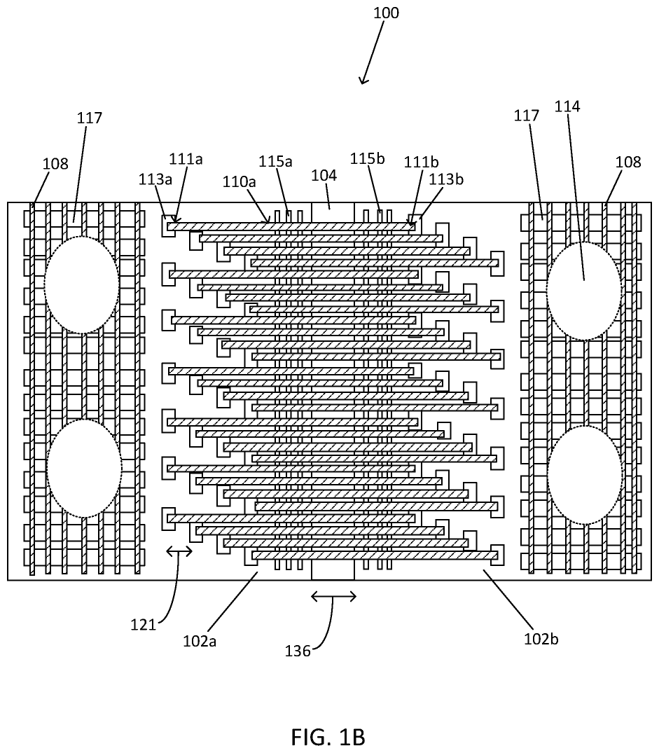

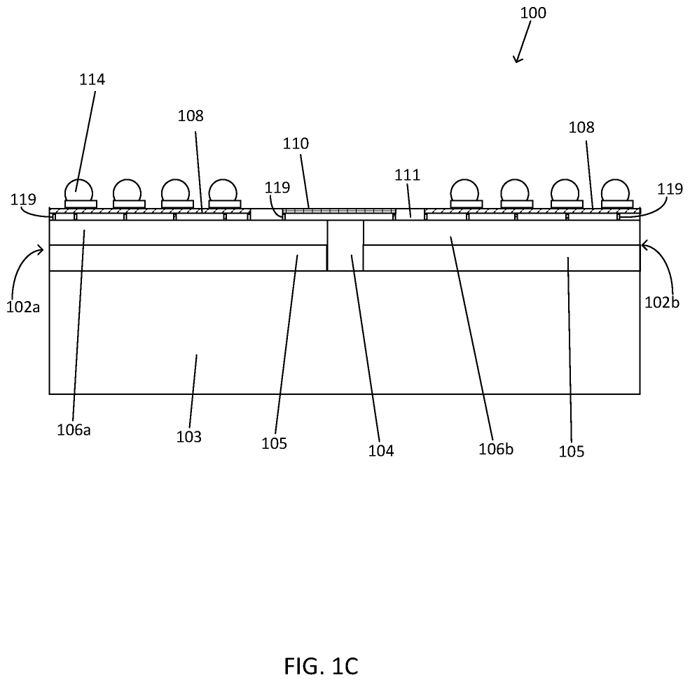

FIGS. 1A-1C illustrate embodiments of package structures including die-to-die bridge structures. The package structures are formed utilizing standard deposition and lithographic processing techniques. The methods of fabrication described herein create very high density interconnect structures to produce the package structures of the embodiments.

FIG. 1A is a cross-sectional view of a portion of integrated circuit (IC) package structure 100, in accordance with some embodiments. As shown, a first die 102a and a second die 102b are on a substrate 151. The first die 102a may comprise an active area 106a on a bulk silicon portion 105. The active area 106a may comprise dielectric materials, such as silicon nitride and or silicon dioxide materials, or any other suitable dielectric materials with metal layers/structures within the dielectric portion materials. In an embodiment, the metal structures may comprise portions of active or passive devices. The active area 106a may comprises integrated circuits/devices and contact structures.

The active area 106a is on a bulk silicon portion 105 of the first die 102a. The second die 102b may likewise comprise an active area 106b comprising IC devices on a bulk silicon portion 105 of the second die 102b. In an embodiment, the first and second dies 102a, 102b may comprise chiplets of a system on a chip (SOC). First and second dies 102a, 102b may comprise any suitable die/device including, but not limited to, a microprocessor, a chipset, a graphics device, a wireless device, a memory device, an application specific integrated circuit, a transceiver device, an input/output device, stacks thereof, or the like.

The active areas 106a, 106b of the first and second dies 102a, 102b may comprise any number of devices such as active and/or passive devices. For example, the active areas 106a, 106b of the first and second dies 102a, 102b may comprise transistor devices and/or resistor structures. In an embodiment, the bulk silicon portions 105 of the first and second dies 102a, 102b may comprise silicon and/or silicon alloys. The first and second dies 102a, 102b may comprise a first side 107 and a second side 109. A die spacer 104 may be between the first and second dies 102a, 102b. The die spacer 104 may comprise a dielectric material, such as a silicon dioxide material, for example.

A bridge structure 110 may be on portions of the first sides 107 of the first and second dies 102a, 102b. The bridge structure 110, which may comprise an interconnect bridge structure, communicatively couples the first and second dies 102a, 102b to each other. In an embodiment, the bridge structure 110 comprises a die-to-die bridge interconnect region. In an embodiment the bridge structure 110 comprises via structures (as shown in FIG. 1C), which are in direct contact with conductive pads on the active areas 106a, 106b of the first and second dies 102a, 102b. The bridge structure 110 allows signal transfer between the adjacent dies 102a, 102b. In some embodiments, there may be multiple levels of the bridge structure 110, depending upon the particular wiring density requirements for an application. The bridge structure 110 comprises a plurality of conductive traces, such as depicted in FIG. 1B, for example.

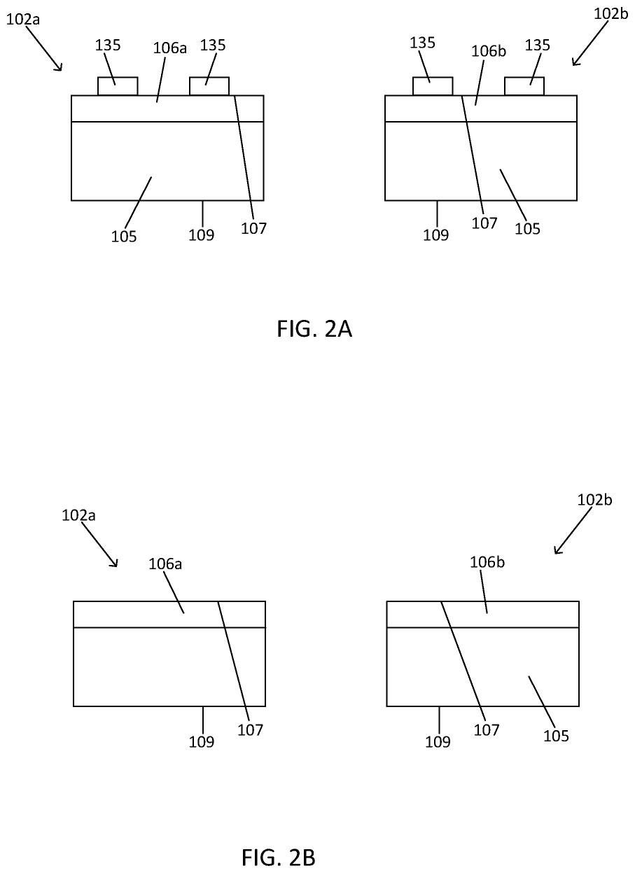

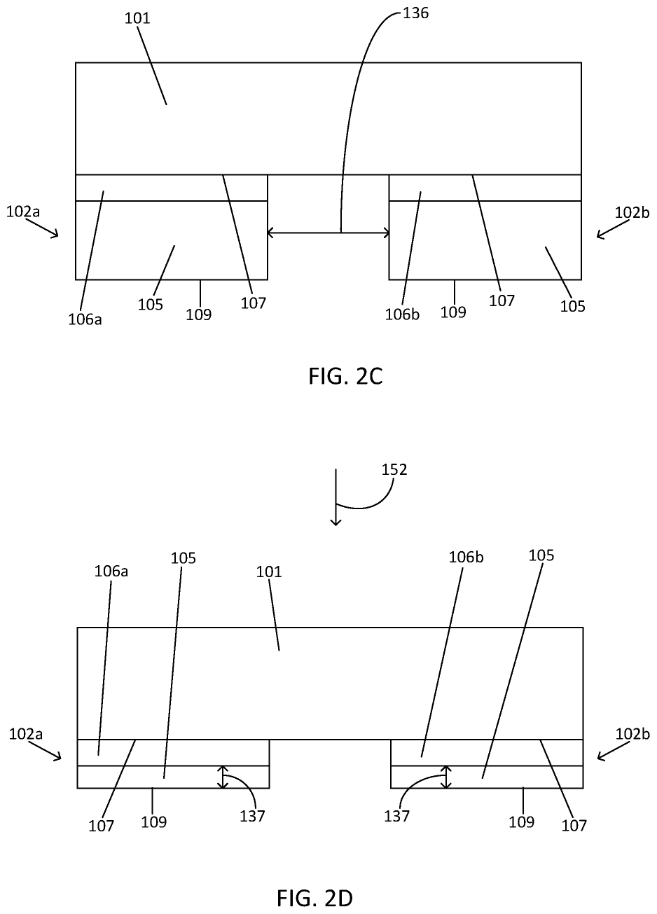

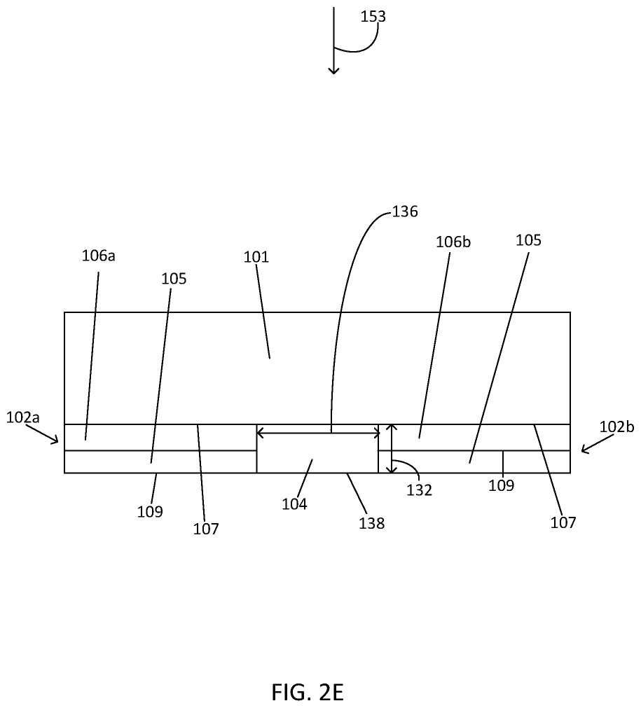

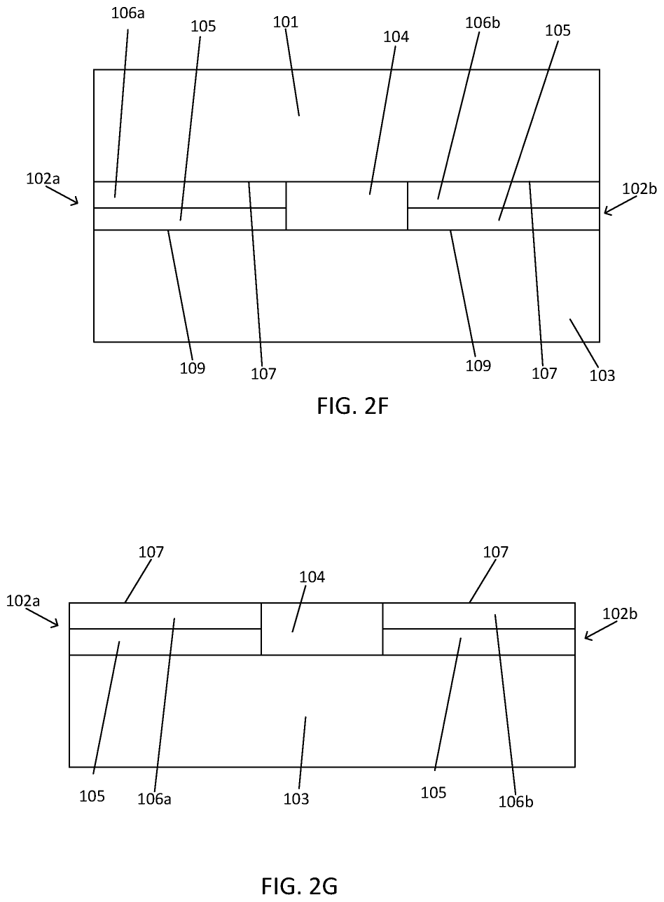

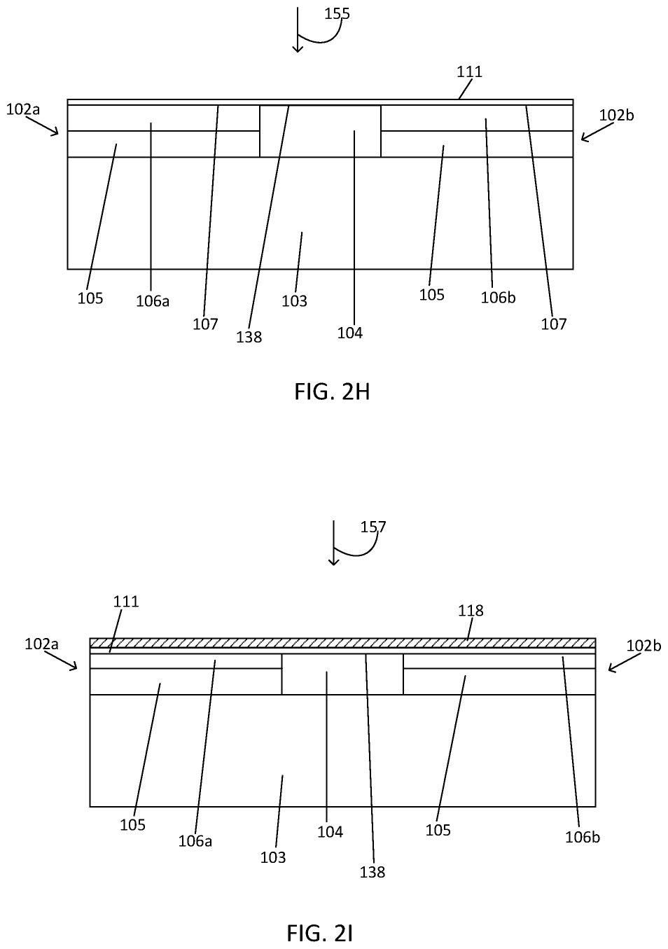

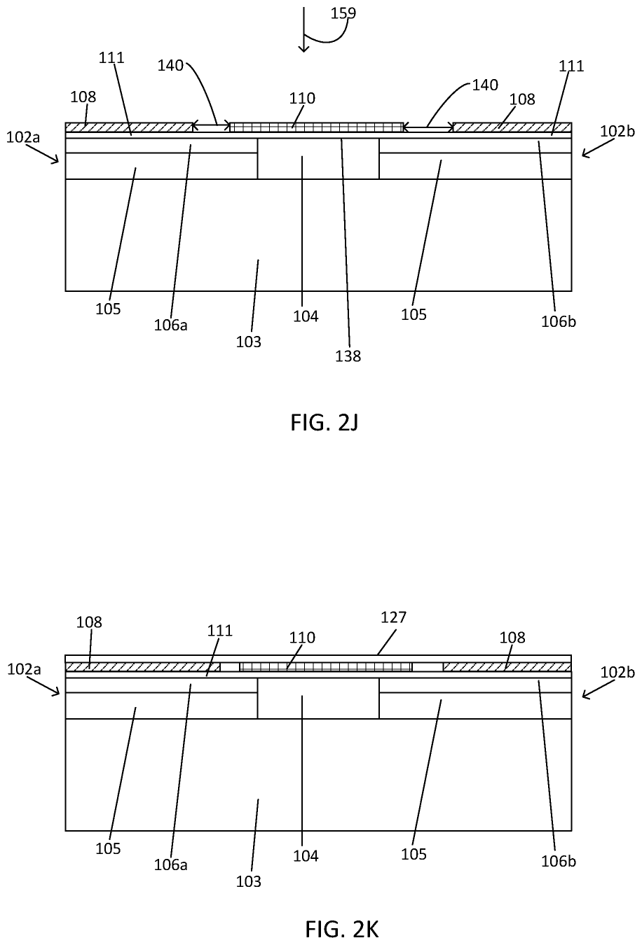

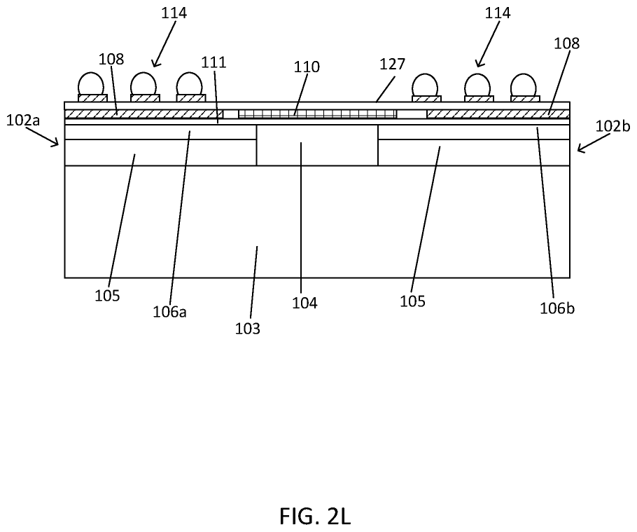

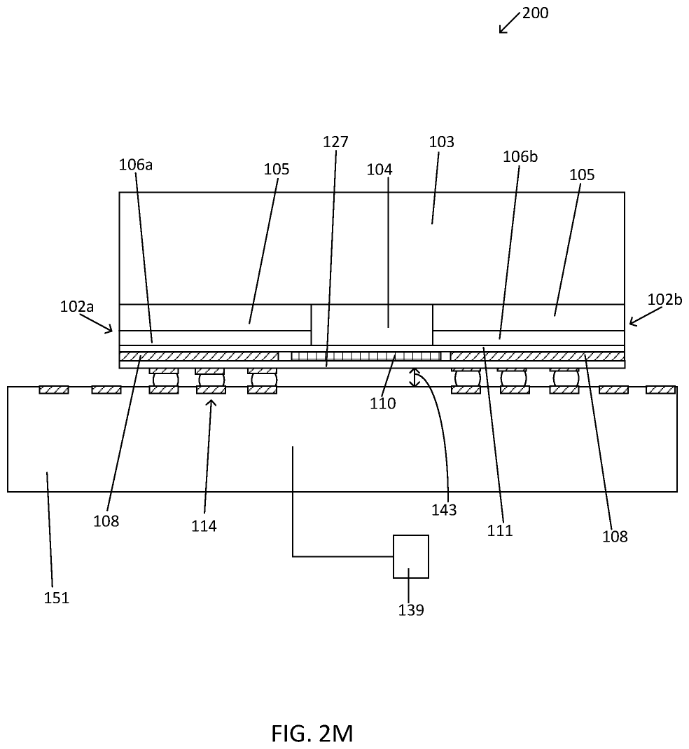

System level metal regions 108 are adjacent to the bridge structure 110 and are in the same metal layer as the bridge structure 110. The system level metal regions 108 are in the same metal layer/plane as the bridge structure 110 and are formed in the same deposition and patterning process as the bridge structure 110. The system level metal regions 108 comprise a plurality of conductive traces. The system level metal regions 108 are not contiguous with the bridge structure 110. As depicted in FIG. 2J, a distance 140 is between the system level metal regions 108 and the bridge structure 110, wherein an insulator material is between the system level metal region 108 and the bridge structure 110.

The system level metal regions 108 are directly on the active areas 106a, 106b of the first and second dies 102a, 102b. An opposite side of the system level metal regions 108 are on conductive bumps 114, which are coupled to the package substrate 151. The conductive bumps 114 may comprise any conductive element for coupling to an outside die or other device. In an embodiment, the conductive bumps 114 may include one or more of silver, tin, or copper, or combinations or alloys thereof. The bridge structure 110 is not over the conductive bumps 114.

The package substrate 151 comprises dielectric layers 116 and conductive layers 118. The conductive layers 118 may comprise any suitable conductive metals and their alloys, such as copper, gold, silver, titanium, tungsten and their alloys, for example. The conductive layers 118 may comprise portions of devices and/or routing conductive layers within a die/device. The package substrate 151 may comprise any suitable substrate such as a printed circuit board, for example. The package substrate 151 may comprise package bumps 120. A thermal solution 103 is coupled to second sides 109 of the first and second dies 102a, 102b. In an embodiment, the thermal solution comprises a thermo-mechanical silicon wafer.

FIG. 1B is a top view of an IC package structure 100, in accordance with some embodiments. IC package structure 100 includes first and second dies 102a, 102b where a dielectric spacer 104 is between the first die 102a and the second die 102b. The dielectric spacer 104 may comprise a lateral width 136. The bridge structure 110 comprises a plurality of conductive traces which may comprise a plurality of metal lines which span a distance between the first and second dies 102a, 102b. For example, individual conductive trace 110a comprises a first terminal end 111a that is physically coupled with a first contact 113a. The first contact 113a is on the first die 102a. A second terminal end 111b of the individual conductive trace 110a is on a second contact 113b, wherein the second contact 113b is on the second die 102b.

First and second contacts 113a, 113b are on the active areas of the first and second dies 102a, 102b respectively. The contacts 113 on the first and second dies 102a, 102b are conductive structures which couple the bridge structure 110 with the first and second dies 102a, 102b. The contact structures 113 comprise conductive materials such as copper or copper alloys, for example. A pitch 121 between adjacent contact structures may comprise about 9 microns or below, in an embodiment, but may vary upon particular design requirements of the application. A pitch between adjacent metal traces 110 may be between about 0.2 and 10 microns.

System level metal regions 108 are adjacent to the bridge structure 110, wherein the system level metal regions 108 comprise a plurality of conductive traces. In an embodiment, the system level metal regions 108 are orthogonally aligned with the bridge structure 110 and are over final metal traces 117. In other embodiments, the system level metal regions 108 may be parallel to the bridge structure 110 or may be in any suitable orientation relative to the bridge structure 110. In an embodiment, conductive bumps 114 are over the system level metal regions 108 but are not over the bridge structure 110. In other embodiments, conductive bumps may be over and may conductively couple to the bridge structure 110. Silicon level metal layer processes enable very high density conductive trace fabrication. In an embodiment, about 1K wires/mm and higher per layer may be realized according to the embodiments herein. For example, 9 micron pad pitch 121, or denser, may be fabricated utilizing a reconstituted wafer process. This dense interconnect pad pitch 121 minimizes active area usage and thus significantly reduces the cost associated with die disaggregation. The finer pad pitch along with reduced scribe line area enabled by plasma dicing process, can result in very short interconnect/conductive trace length of around 200 μm or less for 1K wires/mm wiring density per layer. Thus, the bridge structure 110 produces higher bandwidth and lower power SOC structures.

Guard ring structures 115a, 115b are on the active areas of the first and second dies 102a, 102b respectively. Metal layers 117 are on the surfaces of the active areas of the first and second dies 102a, 102b.

An inorganic dielectric layer 111 (FIG. 1C) is on the active areas 106a, 106b of the first and second dies 102a, 102b and over the metal layers 117, which may be the last/final metal layers 117 on the active areas 106a, 106b. The bridge structure 110 and the system level metal regions 108 are on the inorganic dielectric layer 111, wherein via structures 119 are embedded within the inorganic dielectric layer 111 and couple various IC circuit structures of the first and second dies 102a, 102b with the bridge structure 110 and system level metal regions 108. The inorganic dielectric layer 111 (which does not appreciably comprise carbon-based compounds and/or polymers) comprises any suitable inorganic materials such as a silicon nitride or a silicon oxide material, for example. A thermal solution 103 is on the bulk silicon regions 105 of the first and second dies 102a, 102. A dielectric spacer 104 is between the first and second dies 102a, 102b and a surface of the dielectric spacer is on the thermal solution 103. Conductive bumps 114 are on the system level metal regions 108 but are not over/on the bridge structure 110.

FIGS. 2A-2M illustrate embodiments of forming IC package structures (such as the IC package structures of FIGS. 1A-1C). FIG. 2A depicts a cross-sectional view of a portion of IC die/device/wafer structures according to some embodiments. As shown, a first die 102a and a second die 102b are depicted. In some embodiments, any number of dies may be utilized. In some embodiments, the first and second dies 102a, 102b may comprise chiplet structures 102a, 102b which may comprise components of a system on a chip (SOC) structure. In an embodiment, the dies 102a, 102b may comprise monolithic integrated circuit (IC) wafers or portions of IC wafers.

The dies 102a, 102b may comprise a first side 107 and a second side 109. The dies 102a, 102b may comprise sort pads 135 on active areas 106a, 106b such that the dies 102a, 102b may be tested prior to the incorporation of the dies 102a, 102b into a package structure. The active areas 106a, 106b comprise device circuitry and the bulk silicon portions 105 are on the active portions 106a, 106b of the of dies 102a, 102b. In FIG. 2B, the sort pads 135 may optionally be removed from the dies 102a, 102b.

A temporary carrier 101 may be attached to first sides 107 of the first and second dies 102a, 102b (FIG. 2C). The first sides 107 of the first and second dies 102a, 102b may be fusion bonded to the surface of the temporary carrier 101 wherein covalent bonds may be formed between the first sides 107 and the temporary carrier 101. In an embodiment, the temporary carrier 101 may comprise a silicon wafer. The first and second dies 102a, 102b are adjacent to one another on the temporary carrier 101, wherein there is a distance 136 between the dies 102a, 102b. A thickness 137 of the second sides 109 of the first and second dies 102a, 102b may be reduced by employing a grinding process 152 (FIG. 2D). The reduced thickness 137 of the first and second dies 102a, 102b may comprise between about and 10 microns to about 40 microns.

A dielectric spacer 104 may be formed in the space between the first and second dies 102a, 102b utilizing any suitable formation process 153, such as a plasma formation process, for example (FIG. 2E). The dielectric spacer 104 may comprise any suitable dielectric materials, such as silicon, oxygen or nitrogen materials, or any other suitable dielectric materials. A surface 138 of the dielectric spacer 104 may be coplanar with the second sides 109 of the first and second dies 102a, 102b, so that a height 132 of the dielectric spacer is substantially the same as the height 132 of the first and second dies 102a, 102b. In an embodiment, subsequent to dielectric spacer 104 formation, the second sides 109 of the first and second dies 102a, 102b may undergo a polishing process, such as a chemical mechanical polishing (CMP) process, to prepare for a fusion bonding process.

A thermal solution 103 may be fusion bonded to the surfaces 109 of the first and second dies 102a, 102b (FIG. 2F) wherein hydrogen covalent bonds are formed between the second surfaces 109 of the first and second dies 102a, 102b and the thermal solution 103. In an embodiment, the thermal solution 103 may comprise a thermo-mechanical silicon wafer. The temporary carrier 101 may then be removed from the first sides 107 of the first and second dies 102a, 102b, and the first sides 107 of the first and second dies 102a, 102b may undergo a polishing process (FIG. 2G).

As depicted in FIG. 2H, an inorganic dielectric layer 111 may be formed on the first sides 107 of the first and second dies 102a, 102b as well as on the surface 138 of the dielectric spacer 104. In an embodiment, the inorganic dielectric layer 111 may be formed by utilizing a formation process 155, which may comprise any suitable formation process, such as a plasma process or a thermally grown film, for example. In an embodiment, the inorganic dielectric layer 111 may comprise a thickness of about 0.5 microns to about 1.5 microns and may comprise such inorganic films as silicon oxide or silicon nitride, and the like.

In an embodiment, a conductive layer 118 may be formed on the inorganic dielectric layer 111, over the first and second dies 102a, 102b, by utilizing a formation process 157 (FIG. 2I). For example, an electroplating process or a sputtering process may be employed to form a conductive layer 118 on the inorganic dielectric layer 111. In an embodiment, the conductive layer 118 may comprise copper or copper alloys. In other embodiments, the conductive layer 118 may comprise any suitable conductive materials such as aluminum and its alloys. In an embodiment, the conductive layer 118 may comprise a thickness between about 0.2 microns and 5 microns. In an embodiment, more than one conductive layer 118 may be formed over the inorganic dielectric layer 111 and may be subsequently patterned.

The conductive layer 118 may be patterned by undergoing a patterning process 159, wherein a plurality of conductive traces may be formed over the inorganic dielectric layer 111 (FIG. 2J). In an embodiment, the patterning process 159 may comprise a damascene process, such as a single or a double damascene process, as is known in the art. A bridge structure 110 comprising a first plurality of conductive traces is formed/patterned over a portion of the first and second dies 102a, 102b and over the surface 137 of the dielectric spacer 104.

The bridge structure 110 communicatively couples the first and second dies 102a, 102b to each other. The bridge structure 110 may comprise via structures (such as the via structures 119 of FIG. 1C) that physically and electrically couple the bridge structure 110 to active areas 106a, 106b of the first and second dies 102a, 102b. In an embodiment, via structures may be formed through the dielectric layer 111 (i.e. between the conductive layer 118 and a nearest metal layer, such as metal layers within the active areas 106a, 106b). Both the via metal and layer 118 metal can be formed in a single step using a dual damascene process or may be formed sequentially utilizing a multiple step damascene process such as a via first, followed by a metallization process.

System level metal regions 108 are adjacent to the bridge structure 110, wherein there is a distance 140 between the bridge structure 110 and the system level metal regions 108. In another embodiment, the system level regions 108 and the bridge structure 110 may be continuous, wherein there is no distance 140 between the system level regions 108 and the bridge structure 110. The signal metal between the dies may continue over the area 140, so it can provide metal interconnection between system metal region 108 of one die to the adjacent die using the bridge structure 110 region. The bridge structure 110 together with the system metal region 108 create multi-die system fabric metal interconnects.

The inorganic dielectric layer 111 is within the distance 140 between the bridge structure 110 and the system level metal regions 108. The system level metal regions 108 comprise a second and third plurality of conductive traces that are physically coupled with the active areas 106a, 106b of the first and second dies 102a, 102b by vias (such as the via structures 119 of FIG. 1C). The system level metal regions 108 are over portions of the first and second dies 102a, 102b. The system level metal regions 108 are in the same plane as the bridge structure 110 since they are patterned from the same conductive material 118 and may be formed utilizing the patterning process 159. In an embodiment, multiple levels of bridge structures 110 and system level metal regions 108 may be formed over the first and second dies 102a, 102b, and may be physically and electrically coupled to the active areas 106a, 106b of the first and second dies 102a, 102b.

In an embodiment, a passivation layer 127 may be formed over the bridge structure 110 and the system level regions 108 (FIG. 2K). The passivation layer 127 may comprise a silicon nitride material, in an embodiment, but may comprise any suitable dielectric material. The passivation layer 127 may comprise a thickness of about 1 to about 10 microns in an embodiment. The passivation layer 127 may be patterned and conductive bumps 114 may be formed on the system level metal regions 108 and over portions of the first and second dies 102a, 102b (FIG. 2L). The conductive bumps 114 are not over the bridge structure 110. A package substrate 151 may be attached to the conductive bumps 114 to form a package structure 200 (FIG. 2M). in an embodiment but may be present in other embodiments.

FIG. 2M depicts an IC package structure 200, wherein dies 102a, 102b are on a substrate 151, such as a package substrate 151. The dice 102a, 102b are coupled to each other by the bridge structure 110, and additionally comprise system level metal regions 108 adjacent to the bridge structure. The bridge structure 110 and system level metal regions 108 are directly on the active areas 106a, 106b of the first and second dies 102a, 102b. The dies 102a, 102b may be conductively coupled to the package 151 by conductive bumps 114. The conductive bumps 114 may comprise any conductive element for coupling to an outside die or other device. In an embodiment, the conductive bumps 136 may include one or more of silver, tin, or copper, or combinations or alloys thereof. A power supply 139 which may comprise any suitable power supply as known in the art, may be coupled to dies 102a, 102b via IC package structure 200, in an embodiment.

Discussion now turns to operations for assembling and/or fabricating the discussed structures.

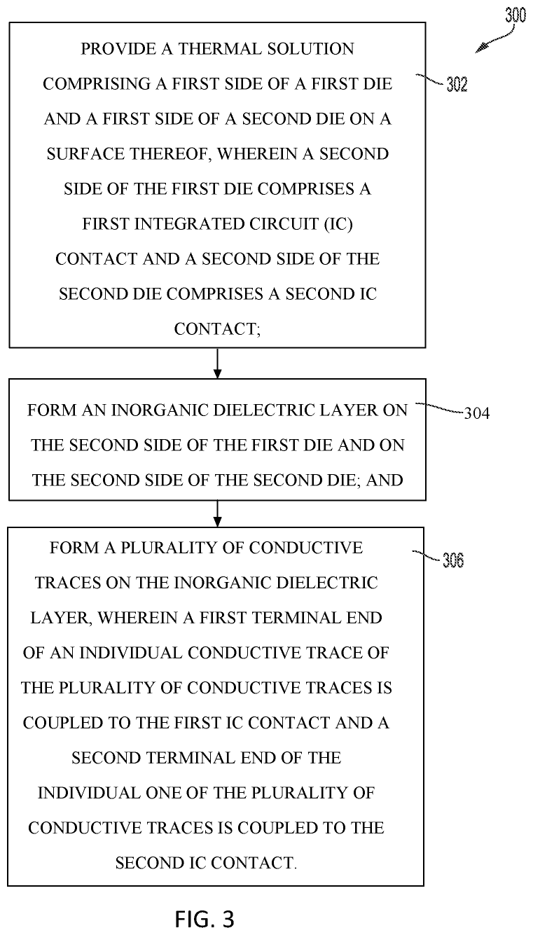

FIG. 3 is a flow chart of a process 300 of fabricating package structures according to some embodiments. For example, process 300 may be used to fabricate any of the microelectronic IC package structures of FIGS. 2A-2K.

As set forth in block 302, a thermal solution is provided wherein a first side of a first die and a first side of a second die are on a surface of the thermal solution. In an embodiment, the thermal solution may comprise a bulk silicon wafer, such as a thermomechanical silicon wafer. In an embodiment, the thermal solution may comprise a thickness of about 80 microns to about 700 microns. First sides of a first die and a second die are on a surface of the thermal solution. In an embodiment, the first sides of the dies may be bonded to the thermal solution by fusion bonding, wherein hydrogen covalent bonding is employed to bond the silicon surface of the thermal solution to the bulk silicon surfaces of the first sides of the first and second dies. In an embodiment, the dies may comprise any suitable die/device, and may comprise chiplets of a system on a chip (SOC). In an embodiment, any number of dies/chiplets may be on the surface of the thermal solution. In an embodiment, the dies may comprise a height of about 10 microns to about 40 microns.

In an embodiment, the first and second dies are adjacent to one another on the surface of the thermal solution, where a dielectric spacer is between the first and second dies. In an embodiment, the dielectric spacer may comprise one or more of silicon, oxygen or nitrogen. The dielectric spacer is on sidewalls of the first and second dies wherein a first side of the dielectric spacer may be coplanar with the first sides of the first and second dies. The dielectric spacer may comprise an inorganic dielectric material such as a silicon dioxide material, for example, and may be formed by any suitable formation process such as a thermally grown dielectric or a CVD process, for example.

A second side of the dielectric spacer may be coplanar with second sides of the first and second dies. In an embodiment, the second sides of the first and second dies may comprise active areas, such as IC active circuit areas of the first and second dies. The active areas comprise a plurality of IC circuit features, such as IC contact structures. In an embodiment, a first IC contact may be on the active area of the first die and a second IC contact may be on the active area of the second die. In an embodiment, the active areas may comprise any suitable shape, such as a circular or a rectangular shape, and may comprise a pitch between individual IC contacts of between about 1 and 10 microns.

At step 304, an inorganic dielectric layer may be formed on a second side of the first die and on a second side of the second die. The inorganic dielectric layer may be formed on the dielectric spacer as well. In an embodiment, the inorganic dielectric layer may be formed by utilizing a plasma processing technique, or by any other suitable formation process. In an embodiment, the inorganic dielectric layer may comprise a thickness of about 0.5 microns to about 1.5 microns but may comprise any suitable thickness according to the particular design needs. In an embodiment the dielectric layer may comprise a silicon dioxide layer but may comprise any suitable dielectric material.

At step 306, a plurality of conductive traces may be formed on the inorganic dielectric layer. The plurality of conductive traces may comprise a metal such as copper or copper alloys, for example, and may provide a conductive interconnecting bridge between the first die and the second die. In an embodiment, the individual conductive traces of the plurality of conductive traces are on the second side of the first die and on the second side of the second die. The plurality of conductive traces may be formed by any suitable formation processes, such as a plating process followed by lithographic processes to deposit and pattern appropriate individual conductive trace geometries. In an embodiment, a damascene process may be employed, wherein a plurality of via structures may be formed which may couple the bridge structure with underlying conductive features on the second sides of the first and second dies. In an embodiment, a first terminal end of an individual conductive trace may be coupled to a first IC contact of the first die and a second terminal end of the individual trace may be coupled to a second IC contact on the second die.

In an embodiment, multiple layers of conductive traces may be formed over the inorganic layer, where each additional layer of metal may be patterned into a plurality of conductive traces each separated by an additional inorganic dielectric layer. In an embodiment, a final layer of metal formed and patterned into conductive traces may be formed over organic dielectric layers.

The embodiments described herein enable the fabrication of high bandwidth, low power interconnect bridge structures between disaggregated silicon chiplets such as die, tiles, or components, for example. The embodiments provide cost effective, high performance system on chip (SoC) structures.

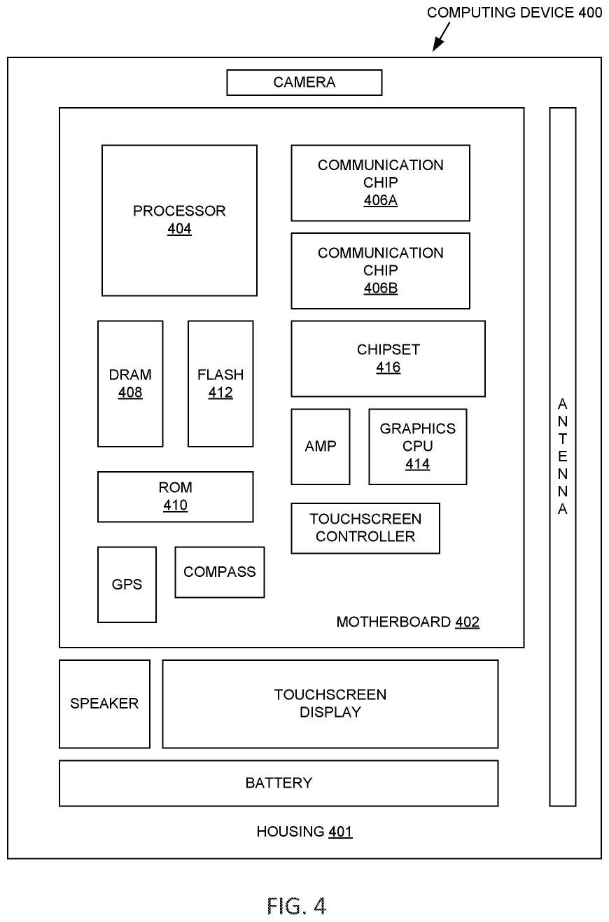

FIG. 4 illustrates an electronic or computing device 400 in accordance with one or more implementations of the present description. The computing device 400 may include a housing 401 having a board 402 disposed therein. The computing device 400 may include a number of integrated circuit components, including but not limited to a processor 404, at least one communication chip 406A, 406B, volatile memory 408 (e.g., DRAM), non-volatile memory 410 (e.g., ROM), flash memory 412, a graphics processor or CPU 414, a digital signal processor (not shown), a crypto processor (not shown), a chipset 416, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 402. In some implementations, at least one of the integrated circuit components may be a part of the processor 404.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory. At least one of the integrated circuit components may include a package substrate, a first die over the package substrate, a second die adjacent the first die, and a bridge structure, wherein at least a portion of the bridge structure is directly on an active side of the first die and is directly on an active side of the second die.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure. It is understood that the subject matter of the present description is not necessarily limited to specific applications illustrated in FIGS. 1-4. The subject matter may be applied to other integrated circuit devices and assembly applications, as well as any appropriate electronic application, as will be understood to those skilled in the art.

The following examples pertain to further embodiments and specifics in the examples may be used anywhere in one or more embodiments, wherein a first example is an apparatus comprising a first die having a first side and a second side. A second die is adjacent to the first die, the second die comprising a first side and a second side. A dielectric spacer is in a space between the first die and the second die and a bridge structure is interconnected the first die and the second die. The bridge structure spans the space between the first die and the second die. A first portion of the bridge structure is directly on a first metal feature of the first side of the first die, and a second portion of the bridge structure is directly on a second metal feature of the first side of the second die. A package substrate is on the first side of the first die and the first side of the second die, wherein the dies are coupled to a first side of the package substrate.

In second examples, the first example further comprises wherein a thermal solution is on the second sides of the first die and the second die.

In third examples, the second example further comprises wherein the thermal solution comprises a bulk silicon wafer.

In fourth examples, the first example further comprises wherein the bridge structure comprises a plurality of conductive traces on an inorganic dielectric layer, wherein a first terminal end of an individual one of the plurality of conductive traces is coupled to the first metal feature and a second terminal end of the individual one of the plurality of conductive traces is coupled to the second metal feature.

In fifth examples, the fourth example further comprises wherein a first side of the dielectric spacer is directly on the thermal solution and the inorganic dielectric layer is between the bridge structure a second side of the dielectric spacer.

In sixth examples, the fourth example further comprises wherein a system level metal region is adjacent and non-contiguous with the bridge structure, wherein the system level metal region comprises a thickness that is substantially the same as a thickness of the bridge structure, and wherein the inorganic dielectric layer is between the system metal layer region and the second die active area.

In seventh examples, the sixth example further comprises wherein the system level metal region comprises a plurality of conductive traces wherein each individual one of the plurality of conductive traces comprises one or more via structures, wherein the one or more via structures are in direct contact with the active region of the first die active area or the second die active area.

In eighth examples, the sixth example further comprises wherein one or more conductive bumps are on the system level metal region and are adjacent to the bridge structure.

In the ninth examples, the eighth example further comprises wherein one or more conductive bumps are on the system level metal region and are adjacent to the bridge structure.

In the tenth examples, the first example further comprises wherein the first side of the first die comprises a first die active area and the first side of the second die comprise a second die active area, wherein an inorganic dielectric layer is on the first die active area and is on the second die active area.

In the eleventh examples, the tenth example further comprises wherein the bridge structure comprises copper or copper alloys and the dielectric layer comprises at least one of silicon, oxygen, nitrogen or carbon.

A twelfth example is a system comprising a first side of a first die on a surface of a thermal solution, wherein a first side of a second die is adjacent the first die. A bridge structure is on a second side of the first die and on a second side of the second die, wherein a first portion of the bridge structure is directly on a first metal feature of the second side of the first die, and a second portion of the bridge structure is directly on a second metal feature of the second side of the second die; and a package substrate, wherein the second side of the first die and the second side of the second die are coupled to the package substrate, wherein the bridge structure comprises a plurality of conductive traces, wherein a dielectric spacer is between the first die and the second die and wherein the bridge structure is over the dielectric spacer.

In the thirteenth examples, the twelfth example further comprises wherein the bridge structure comprises a plurality of conductive traces, wherein a dielectric spacer is between the first die and the second die and wherein the bridge structure is over the dielectric spacer.

In the fourteenth examples, the thirteenth example further comprises wherein a length of an individual one of the plurality of conductive trace structures comprises less than about 200 microns, and wherein a pitch between a first individual one of the plurality of conductive trace structures and a second individual one of the plurality of conductive trace structures comprises less than about 2 microns.

In the fifteenth examples, the thirteenth example further comprises wherein the first metal feature comprises a first integrated circuit (IC) contact structure and the second metal features comprises a second IC contact structure, wherein a first via structure of an individual one of the plurality of contact traces is directly on the first IC contact structure and a second via structure of the individual one of the plurality of contact structures is directly on the second IC contact structure.

In the sixteenth examples, the fifteenth example further comprises wherein a pitch between the first integrated circuit (IC) contact structure and the second IC contact structure is less than about 9 microns, and wherein a power supply is coupled with the first die and the second die.

The seventeenth example is a method, comprising: providing a thermal solution comprising a first side of a first die and a first side of a second die on a surface thereof, wherein a second side of the first die comprises a first integrated circuit (IC) contact structure and wherein a second side of the second die comprises a second IC contact structure, and wherein a dielectric spacer is between the first die and the second die; forming an inorganic dielectric layer on the second side of the first die and on the second side of the second die and on the dielectric spacer; and forming a plurality of conductive traces on the inorganic dielectric layer, wherein a first terminal end of an individual one of the plurality of conductive traces are on the first integrated circuit (IC) contact structure and a second terminal end of the individual one of the plurality of conductive traces are on the second IC contact structure. The method of claim 17, further comprising forming an additional plurality of conductive traces adjacent to the plurality of conductive traces on the inorganic dielectric layer.

In the eighteenth examples, the seventeenth example further comprises forming an additional plurality of conductive traces adjacent to the plurality of conductive traces on the inorganic dielectric layer.

In the nineteenth examples, the eighteenth example further comprises forming one or more conductive bumps on the additional plurality of conductive traces.

In the twentieth examples, the nineteenth example further comprises attaching a package substrate to the one or more conductive bumps.

It will be recognized that principles of the disclosure are not limited to the embodiments so described but can be practiced with modification and alteration without departing from the scope of the appended claims. The above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a first die comprising a first side and a second side;
a second die adjacent the first die, the second die comprising a first side and a second side;
a dielectric spacer in a space between the first die and the second die;
a bridge structure interconnecting the first die and the second die, wherein the bridge structure spans the space between the first die and the second die, a first portion of the bridge structure is directly on a first metal feature of the first side of the first die, and a second portion of the bridge structure is directly on a second metal feature of the first side of the second die; and
a package substrate, wherein the first side of the first die and the first side of the second die are coupled to a first side of the package substrate.

2. The apparatus of claim 1, wherein a thermal solution is on the second sides of the first die and the second die.

3. The apparatus of claim 2, wherein the thermal solution comprises a bulk silicon wafer.

4. The apparatus of claim 1 wherein the bridge structure comprises a plurality of conductive traces on an inorganic dielectric layer, wherein a first terminal end of an individual one of the plurality of conductive traces is coupled to the first metal feature and a second terminal end of the individual one of the plurality of conductive traces is coupled to the second metal feature.

5. The apparatus of claim 2, wherein a first side of the dielectric spacer is directly on the thermal solution and an inorganic dielectric layer is between the bridge structure a second side of the dielectric spacer.

6. The apparatus of claim 4, wherein a system level metal region is adjacent and non-contiguous with the bridge structure, wherein the system level metal region comprises a thickness that is substantially the same as a thickness of the bridge structure, and wherein the inorganic dielectric layer is between the system level metal region and a second die active area.

7. The apparatus of claim 6, wherein the system level metal region comprises a plurality of conductive traces wherein each individual one of the plurality of conductive traces comprises one or more via structures, wherein the one or more via structures are in direct contact with a first die active area or the second die active area.

8. The apparatus of claim 6, wherein one or more conductive bumps are on the system level metal region and are adjacent to the bridge structure.

9. The apparatus of claim 8, wherein a dielectric layer is on the system level metal region, wherein the one or more conductive bumps are adjacent the dielectric layer.

10. The apparatus of claim 1, wherein the first side of the first die comprises a first die active area and the first side of the second die comprises a second die active area, wherein an inorganic dielectric layer is on the first die active area and is on the second die active area.

11. The apparatus of claim 10, wherein the bridge structure comprises copper or copper alloys and the inorganic dielectric layer comprises at least one of silicon, oxygen, nitrogen or carbon.

12. A system, comprising:
a first side of a first die on a surface of a thermal solution;
a first side of a second die adjacent the first die;
a bridge structure on a second side of the first die and on a second side of the second die, wherein a first portion of the bridge structure is directly on a first metal feature of the second side of the first die, and a second portion of the bridge structure is directly on a second metal feature of the second side of the second die; and
a package substrate, wherein the second side of the first die and the second side of the second die are coupled to the package substrate.

13. The system of claim 12, wherein the bridge structure comprises a plurality of conductive traces, wherein a dielectric spacer is between the first die and the second die and wherein the bridge structure is over the dielectric spacer.

14. The system of claim 13, wherein a length of an individual one of the plurality of conductive traces comprises less than about 200 microns, and wherein a pitch between a first individual one of the plurality of conductive traces and a second individual one of the plurality of conductive traces comprises less than about 2 microns.

15. The system of claim 13, wherein the first metal feature comprises a first integrated circuit (IC) contact structure and the second metal features comprises a second IC contact structure, wherein a first via structure of an individual one of the plurality of conductive traces is directly on the first IC contact structure and a second via structure of the individual one of the plurality of conductive traces is directly on the second IC contact structure.

16. The system of claim 15, wherein a pitch between the first integrated circuit IC contact structure and the second IC contact structure is less than about 9 microns, and wherein a power supply is coupled with the first die and the second die.

17. A method, comprising:
providing a thermal solution comprising a first side of a first die and a first side of a second die on a surface thereof, wherein a second side of the first die comprises a first integrated circuit (IC) contact structure and wherein a second side of the second die comprises a second IC contact structure, and wherein a dielectric spacer is between the first die and the second die;
forming an inorganic dielectric layer on the second side of the first die and on the second side of the second die and on the dielectric spacer; and
forming a plurality of conductive traces on the inorganic dielectric layer, wherein a first terminal end of an individual one of the plurality of conductive traces are on the first integrated circuit (IC) contact structure and a second terminal end of the individual one of the plurality of conductive traces are on the second IC contact structure.

18. The method of claim 17, further comprising forming an additional plurality of conductive traces adjacent to the plurality of conductive traces on the inorganic dielectric layer.

19. The method of claim 18, further comprising forming one or more conductive bumps on the additional plurality of conductive traces.

20. The method of claim 19, further comprising attaching a package substrate to the one or more conductive bumps.
